(19) United States
(12) Patent Application Publication
(10) Pub. No.: US 2023/0420471 A1
(43) Pub. Date: Dec. 28, 2023

(54) IMAGE PICKUP ELEMENT AND ELECTRONIC DEVICE

(71) Applicant: SONY SEMICONDUCTOR SOLUTIONS CORPORATION, Kanagawa (JP)

(72) Inventors: Yukihiro SHIRAKI, Kumamoto (JP); Hyoma UTO, Kumamoto (JP)

(73) Assignee: SONY SEMICONDUCTOR SOLUTIONS CORPORATION, Kanagawa (JP)

(21) Appl. No.: 18/252,585

(22) PCT Filed: Nov. 10, 2021
(86) PCT No.: PCT/JP2021/041272

§ 371 Date: May 11, 2023

(30) Foreign Application Priority Data
Nov. 24, 2020 (JP) 2020-194035

(51) Int. Cl. H01L 27/146; G02B 5/00; G02B 5/20

(52) U.S. Cl. CPC H01L 27/14625; H01L 27/14605; H01L 27/14623; G02B 5/008; G02B 5/204

(57) ABSTRACT

The present technology relates to an image pickup element and an electronic device capable of curbing occurrence of blisters. An image pickup element includes: a semiconductor layer in which a first region where a first pixel in which a read pixel signal is used to generate an image is arranged and a second region where a second pixel in which a read pixel signal is not used to generate an image is arranged are arranged; a narrow-band filter that is laminated on the first region on a light incident surface side of the semiconductor layer and transmits light of a desired wavelength; and a metal film that is laminated on the second region on the light incident surface side of the semiconductor layer and has a plurality of through holes. The present technology can be applied to, for example, an imaging device that captures a color image.

### TECHNICAL FIELD

The present technology relates to an image pickup element and an electronic device, and, for example, relates to an image pickup element and an electronic device capable of curbing occurrence of blisters.

### BACKGROUND ART

Conventionally, an image pickup element that detects light (hereinafter also referred to as narrow-band light) in a predetermined narrow wavelength band (narrow band) using a plasmonic filter has been proposed (refer to, for example, Patent Document 1).

### CITATION LIST

### Patent Document

Patent Document 1: Japanese Patent Application Laid-Open No. 2010-165718

### SUMMARY OF THE INVENTION

### Problems to be Solved by the Invention

A plasmonic filter is formed using a metal such as aluminum. It has been proposed to laminate a barrier metal on a metal in order to form a configuration for occluding hydrogen when the hydrogen is generated during processing. When a barrier metal is laminated on a plasmonic filter, the propagation intensity decreases. When a barrier metal is not laminated on a plasmonic filter, blisters may occur.

In a case where a plasmonic filter is used, it is desired to curb the occurrence of blisters without reducing the propagation intensity of the plasmonic filter.

The present technology has been made in view of such a situation, and makes it possible to curb the occurrence of blisters without reducing the propagation intensity of a plasmonic filter.

### Solutions to Problems

An image pickup element according to one aspect of the present technology is an image pickup element including: a semiconductor layer in which a first region where a first pixel in which a read pixel signal is used to generate an image is arranged and a second region where a second pixel in which a read pixel signal is not used to generate an image is arranged are arranged; a narrow-band filter that is laminated on the first region on a light incident surface side of the semiconductor layer and transmits light of a desired wavelength; and a metal film that is laminated on the second region on the light incident surface side of the semiconductor layer and has a plurality of through holes.

An electronic device according to one aspect of the present technology is an electronic device including: an image pickup element having a semiconductor layer in which a first region where a first pixel in which a read pixel signal is used to generate an image is arranged and a second region where a second pixel in which a read pixel signal is not used to generate an image is arranged are arranged, a narrow-band filter that is laminated on the first region on a light incident surface side of the semiconductor layer and transmits light of a desired wavelength, and a metal film that is laminated on the second region on the light incident surface side of the semiconductor layer and has a plurality of through holes; and a processing unit that processes a signal from the image pickup element.

An image pickup element according to one aspect of the present technology includes: a semiconductor layer in which a first region where a first pixel in which a read pixel signal is used to generate an image is arranged and a second region where a second pixel in which a read pixel signal is not used to generate an image is arranged are arranged; a narrow-band filter that is laminated on the first region on a light incident surface side of the semiconductor layer and transmits light of a desired wavelength; and a metal film that is laminated on the second region on the light incident surface side of the semiconductor layer and has a plurality of through holes.

An electronic device according to one aspect of the present technology includes the image pickup element.

### BRIEF DESCRIPTION OF DRAWINGS

FIG. 1 is a diagram for describing a configuration example of an imaging device.

FIG. 2 is a diagram for describing a configuration example of an image pickup element.

FIG. 3 is a diagram for describing a configuration example of a pixel.

FIG. 4 is a diagram for describing a configuration example of a plasmonic filter.

FIG. 5 is a diagram for describing a principle of a plasmonic filter.

FIG. 6 is a diagram for describing light transmitted by a plasmonic filter.

FIG. 7 is a diagram for describing a configuration example of a plasmonic filter.

FIG. 8 is a diagram depicting a configuration example of a plasmonic filter using GMR.

FIG. 9 is a diagram depicting a configuration example of a plasmonic filter having a bull's-eye structure.

FIG. 10 is a diagram for describing an OPB region.

FIG. 11 is a diagram describing a cross-sectional configuration example of a pixel array unit.

FIG. 12 is a graph related to the propagation intensity of a plasmonic filter.

FIG. 13 is a diagram for describing occurrence of blisters.

FIG. 14 is a diagram depicting a planar configuration example of a plasmonic filter.

FIG. 15 is a diagram for describing the shape of holes of the plasmonic filter.

FIG. 16 is a diagram for describing a blister occurrence position.

FIG. 17 is a diagram for describing a positional relationship between holes.

FIG. 18 is a diagram for describing another cross-sectional configuration example of the pixel array unit.

FIG. 19 is a diagram depicting an example of a schematic configuration of an endoscopic surgery system.

FIG. 20 is a block diagram depicting an example of a functional configuration of a camera head and a CCU.

FIG. 21 is a block diagram depicting an example of a schematic configuration of a vehicle control system.

FIG. 22 is an explanatory view depicting an example of installation positions of an outside-vehicle information detecting section and an imaging section.

### MODE FOR CARRYING OUT THE INVENTION

Hereinafter, a mode for carrying out the present technology (hereinafter referred to as embodiment) will be described.

<Configuration Example of Imaging Device>

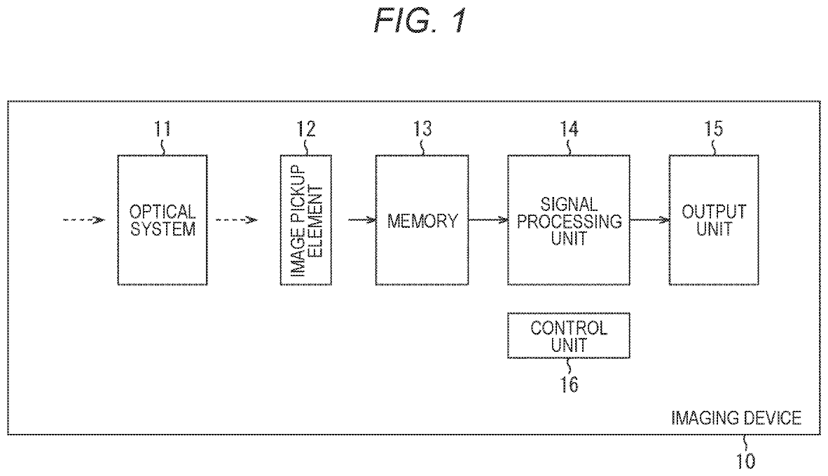

FIG. 1 is a block diagram illustrating an embodiment of an imaging device which is a type of electronic device to which the present technology is applied.

An imaging device 10 in FIG. 1 includes, for example, a digital camera capable of capturing both a still image and a moving image. Furthermore, the imaging device 10 includes, for example, a multispectral camera capable of detecting light (multispectrum) in four or more wavelength bands (four or more bands), which are more than conventional three wavelength bands (three bands) of red (R), green (G), and blue (B), or yellow (Y), magenta (M), and cyan (C) based on the three primary colors or color-matching functions.

The imaging device 10 includes an optical system 11, an image pickup element 12, a memory 13, a signal processing unit 14, an output unit 15, and a control unit 16.

The optical system 11 includes, for example, a zoom lens, a focus lens, a diaphragm, and the like (not illustrated), and causes light from the outside to enter the image pickup element 12. Furthermore, the optical system 11 is provided with various filters such as a polarizing filter as necessary.

The image pickup element 12 includes, for example, a complementary metal oxide semiconductor (CMOS) image sensor. The image pickup element 12 receives incident light from the optical system 11, performs photoelectric conversion, and outputs image data corresponding to the incident light.

The memory 13 temporarily stores image data output from the image pickup element 12.

The signal processing unit 14 performs signal processing (for example, processing such as noise removal and white balance adjustment) using the image data stored in the memory 13 and supplies the processed image data to the output unit 15.

The output unit 15 outputs the image data from the signal processing unit 14. For example, the output unit 15 includes a display (not illustrated) including liquid crystal or the like, and displays a spectrum (image) corresponding to image data from the signal processing unit 14 as a so-called through image. For example, the output unit 15 includes a driver (not illustrated) that drives a recording medium such as a semiconductor memory, a magnetic disk, or an optical disk, and records image data from the signal processing unit 14 on the recording medium. For example, the output unit 15 functions as a communication interface that communicates with an external device (not illustrated), and transmits image data from the signal processing unit 14 to the external device in a wireless or wired manner.

The control unit 16 controls each unit of the imaging device 10 according to a user's operation or the like.

<Configuration Example of Circuit of Image Pickup Element>

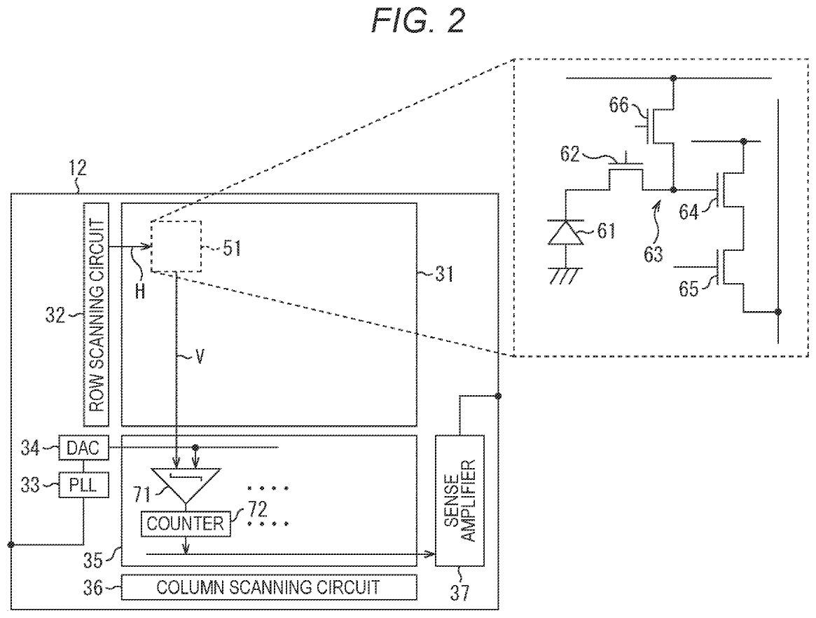

FIG. 2 is a block diagram illustrating a configuration example of a circuit of the image pickup element 12 in FIG. 1.

The image pickup element 12 includes a pixel array unit 31, a row scanning circuit 32, a phase locked loop (PLL) 33, a digital analog converter (DAC) 34, a column analog digital converter (ADC) circuit 35, a column scanning circuit 36, and a sense amplifier 37.

In the pixel array unit 31, a plurality of pixels 51 is arranged in a two-dimensional manner.

Furthermore, the pixels 51 are arranged at intersections of horizontal signal lines H connected to the row scanning circuit 32 and vertical signal lines V connected to the column ADC circuit 35, and include a photodiode 61 that functions as a photoelectric conversion unit that performs photoelectric conversion and several types of transistors for reading accumulated signals. That is, as depicted in an enlarged manner on the right side of FIG. 2, the pixel 51 includes a photodiode 61, a transfer transistor 62, a floating diffusion 63, an amplification transistor 64, a selection transistor 65, and a reset transistor 66.

The charge accumulated in the photodiode 61 is transferred to the floating diffusion 63 via the transfer transistor 62. The floating diffusion 63 is connected to the gate of the amplification transistor 64. When the pixel 51 becomes a signal reading target, the selection transistor 65 is turned on by the row scanning circuit 32 via the horizontal signal line H, and a signal of the selected pixel 51 is read out to the vertical signal line V as a pixel signal corresponding to an accumulated charge amount of the charge accumulated in the photodiode 61 by driving the amplification transistor 64 as a source follower. Furthermore, the pixel signal is reset by turning on the reset transistor 66.

The row scanning circuit 32 sequentially outputs drive signals for driving (for example, transfer, selection, reset, and the like) the pixels 51 of the pixel array unit 31 for each row.

The PLL 33 generates and outputs a clock signal of a predetermined frequency necessary for driving each unit of the image pickup element 12 on the basis of a clock signal supplied from the outside.

The DAC 34 generates and outputs a ramp signal having a shape (substantially saw-like shape) in which a voltage drops from a predetermined voltage value at a constant inclination and then returns to the predetermined voltage value.

The column ADC circuit 35 includes comparators 71 and counters 72 as many as the columns of the pixels 51 of the pixel array unit 31, extracts a signal level from the pixel signal output from the pixel 51 by a correlated double sampling (CDS) operation, and outputs pixel data. That is, the comparator 71 compares the ramp signal supplied from the DAC 34 with the pixel signal (luminance value) output from the pixel 51, and supplies a comparison result signal obtained as a result to the counter 72. Then, the counter 72 counts counter clock signals of a predetermined frequency according to the comparison result signal output from the comparator 71, whereby the pixel signal is A/D converted.

The column scanning circuit 36 sequentially supplies the counter 72 of the column ADC circuit 35 with signals for outputting pixel data at a predetermined timing.

The sense amplifier 37 amplifies the pixel data supplied from the column ADC circuit 35 and outputs the pixel data to the outside of the image pickup element 12.

Note that in the following description, the pixel 51 is also referred to as a light receiving element. Furthermore, the description will be continued on the assumption that the image pickup element 12 includes a plurality of pixels 51 (light receiving elements).

<Configuration of Image Pickup Element>

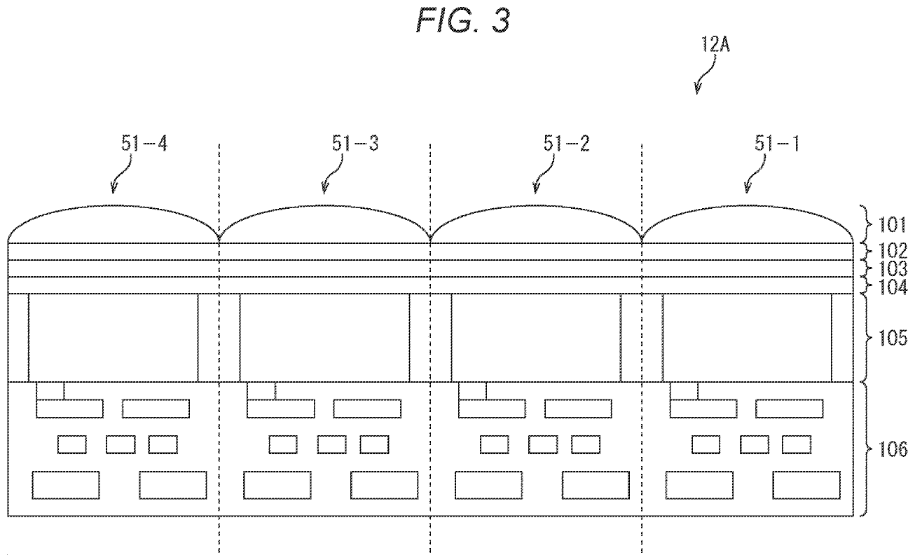

FIG. 3 schematically illustrates a configuration example of a cross section of the image pickup element 12 in FIG. 1. Note that as will be described later, the pixel array unit 31 is provided with a valid pixel region and an invalid pixel region. FIG. 3 illustrates a cross-sectional configuration example of the image pickup element 12 arranged in the valid pixel region, and the configuration of the image pickup element 12 will be described.

FIG. 3 illustrates cross sections of four pixels of pixels 51-1 to 51-4 of the image pickup element 12. Note that hereinafter, in a case where it is not necessary to individually distinguish the pixels 51-1 to 51-4, they are simply referred to as the pixel 51.

In each pixel 51, an on-chip lens 101, an interlayer film 102, a narrow-band filter layer 103, an interlayer film 104, a photoelectric conversion element layer 105, and a wiring layer 106 are laminated in this order from the top. That is, the image pickup element 12 includes a back-illuminated CMOS image sensor in which the photoelectric conversion element layer 105 is arranged on the light incident side of the wiring layer 106.

The on-chip lens 101 is an optical element for condensing light on the photoelectric conversion element layer 105 of each pixel 51.

The interlayer film 102 and the interlayer film 104 include a dielectric such as SiO2. As will be described later, the dielectric constants of the interlayer film 102 and the interlayer film 104 are desirably as low as possible.

In the narrow-band filter layer 103, a narrow-band filter NB that is an optical filter that transmits narrow-band light of a predetermined narrow wavelength band (narrow band) is provided in each pixel 51. For example, a plasmonic filter that is a kind of thin metal film filter using a thin film including metal such as aluminum and uses surface plasmon is used for the narrow-band filter NB. Furthermore, the transmission band of the narrow-band filter NB is set for each pixel 51. The type (number of bands) of the transmission band of the narrow-band filter NB is arbitrary, and is set to, for example, four or more.

Here, the narrow band is, for example, a wavelength band narrower than a transmission band of a conventional R (red), G (green), B (blue), or Y (yellow), M (magenta), C (cyan), or conventional R (red), G (green), or B (blue) color filter based on three primary colors or a color-matching function.

The photoelectric conversion element layer 105 includes, for example, the photodiode 61 in FIG. 2 and the like, receives light (narrow-band light) transmitted through the narrow-band filter layer 103 (narrow-band filter NB), and converts the received light into charge. Furthermore, the photoelectric conversion element layer 105 is configured such that the pixels 51 are electrically separated from each other by an element separation layer.

The wiring layer 106 is provided with wiring or the like for reading charge accumulated in the photoelectric conversion element layer 105.

<Plasmonic Filter>

Next, a plasmonic filter that can be used for the narrow-band filter layer 103 will be described.

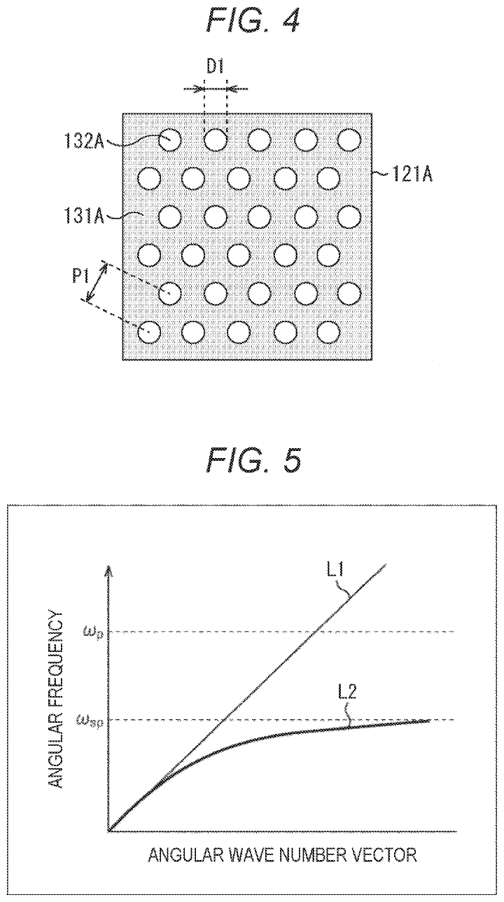

FIG. 4 illustrates a configuration example of a plasmonic filter 121A having a hole array structure (hole array type plasmonic filter 121A).

The plasmonic filter 121A includes a plasmonic resonator in which holes 132A are arranged in a thin metal film (hereinafter referred to as conductor thin film) 131A in a honeycomb shape.

Each hole 132A penetrates the conductor thin film 131A and acts as a waveguide. Commonly, a waveguide has a cutoff frequency and a cutoff wavelength determined by a shape such as a side length and a diameter, and has a property of not propagating light having a frequency equal to or lower than the cutoff frequency (wavelength equal to or higher than the cutoff wavelength). The cutoff wavelength of the hole 132A mainly depends on an opening diameter D1, and the cutoff wavelength becomes shorter as the opening diameter D1 is smaller. Note that the opening diameter D1 is set to a value smaller than the wavelength of light to be transmitted.

On the other hand, when light is incident on the conductor thin film 131A in which the holes 132A are periodically formed at a pitch equal to or less than the wavelength of light, a phenomenon occurs in which light having a wavelength longer than the cutoff wavelength of the holes 132A is transmitted. This phenomenon is referred to as an abnormal transmission phenomenon of plasmon. This phenomenon occurs when surface plasmon is excited at the boundary between the conductor thin film 131A and the interlayer film 102 on the conductor thin film 131A.

Here, with reference to FIG. 5, occurrence conditions of an abnormal transmission phenomenon of plasmon (surface plasmon resonance) will be described.

FIG. 5 is a graph illustrating a dispersion relationship of surface plasmons. The horizontal axis of the graph represents an angular wave number vector k, and the vertical axis represents an angular frequency ω. Reference sign ωₚ represents a plasma frequency of the conductor thin film 131A. Reference sign ωₛₚ represents a surface plasma frequency at a boundary surface between the interlayer film 102 and the conductor thin film 131A, and is expressed by the following equation (1).

$$\begin{matrix}[ Math 1 ] & \\ {ω}_{sp} = \frac{{ω}_{p}}{\sqrt{1 + {ε}_{d}}} & ( 1 )\end{matrix}$$

Reference sign ε_{d} represents the dielectric constant of the dielectric included in the interlayer film 102.

According to equation (1), the surface plasma frequency wₛₚ increases as the plasma frequency ωₚ increases. Furthermore, the surface plasma frequency wₛₚ increases as the dielectric constant ε_{d} decreases.

Line L1 indicates a light dispersion relationship (light line) and is expressed by the following equation (2).

$$\begin{matrix}[ Math 2 ] & \\ ω = \frac{c}{\sqrt{{ε}_{d}}} k & ( 2 )\end{matrix}$$

Reference sign c represents the speed of light.

Line L2 indicates a dispersion relationship of surface plasmons and is expressed by the following equation (3).

$$\begin{matrix}[ Math 3 ] & \\ ω = ck \sqrt{\frac{{ε}_{m} + {ε}_{d}}{{ε}_{m} {ε}_{d}}} & ( 3 )\end{matrix}$$

Reference sign εₘ represents the dielectric constant of the conductor thin film 131A.

The dispersion relationship of the surface plasmons represented by line L2 asymptotically approaches the light line represented by line L1 in a range where the angular wave number vector k is small, and asymptotically approaches the surface plasma frequency ωₛₚ as the angular wave number vector k increases.

Then, when the following equation (4) holds, an abnormal transmission phenomenon of plasmon occurs.

$$\begin{matrix}[ Math 4 ] & \\ Re [ \frac{{ω}_{sp}}{c} \sqrt{\frac{{ε}_{m} + {ε}_{d}}{{ε}_{m} {ε}_{d}}} ] = \vert \frac{2 π}{λ} sin θ + {iG}_{x} + {jG}_{y} \vert & ( 3 )\end{matrix}$$

Reference sign λ represents a wavelength of incident light. Reference sign θ represents an incident angle of incident light. Values of Gₓ and G_{y} are expressed by the following equation (5).

|Gₓ|=|G_{y}|=2π/a₀ (5)

Reference sign a₀ represents a lattice constant of a hole array structure including the holes 132A of the conductor thin film 131A.

The left side of equation (4) represents the angular wave number vector of the surface plasmon, and the right side represents the angular wave number vector of the hole array period of the conductor thin film 131A. Therefore, when the angular wave number vector of the surface plasmon is equal to the angular wave number vector of the hole array period of the conductor thin film 131A, an abnormal transmission phenomenon of plasmon occurs. Then, the value of λ at this time becomes a plasmon resonance wavelength (transmission wavelength of plasmonic filter 121A).

Note that the angular wave number vector of the surface plasmon on the left side of equation (4) is determined by the dielectric constant εₘ of the conductor thin film 131A and the dielectric constant ε_{d} of the interlayer film 102. On the other hand, the angular wave number vector of the hole array period on the right side is determined by the incident angle θ of light and a pitch (hole pitch) P1 between adjacent holes 132A of the conductor thin film 131A. Therefore, the resonance wavelength and the resonance frequency of plasmon are determined by the dielectric constant εₘ of the conductor thin film 131A, the dielectric constant ε_{d} of the interlayer film 102, the incident angle θ of light, and the hole pitch P1. Note that in a case where the incident angle of light is 0°, the resonance wavelength and the resonance frequency of plasmon are determined by the dielectric constant εₘ of the conductor thin film 131A, the dielectric constant ε_{d} of the interlayer film 102, and the hole pitch P1.

Therefore, the transmission band (resonance wavelength of plasmon) of the plasmonic filter 121A changes depending on the material and film thickness of the conductor thin film 131A, the material and film thickness of the interlayer film 102, the pattern period (for example, the opening diameter D1 and the hole pitch P1 of the hole 132A) of the hole array, and the like. In particular, in a case where the material and film thickness of the conductor thin film 131A and the interlayer film 102 are determined, the transmission band of the plasmonic filter 121A changes depending on the pattern period of the hole array, particularly the hole pitch P1. That is, as the hole pitch P1 narrows, the transmission band of the plasmonic filter 121A shifts to the short wavelength side, and as the hole pitch P1 widens, the transmission band of the plasmonic filter 121A shifts to the long wavelength side.

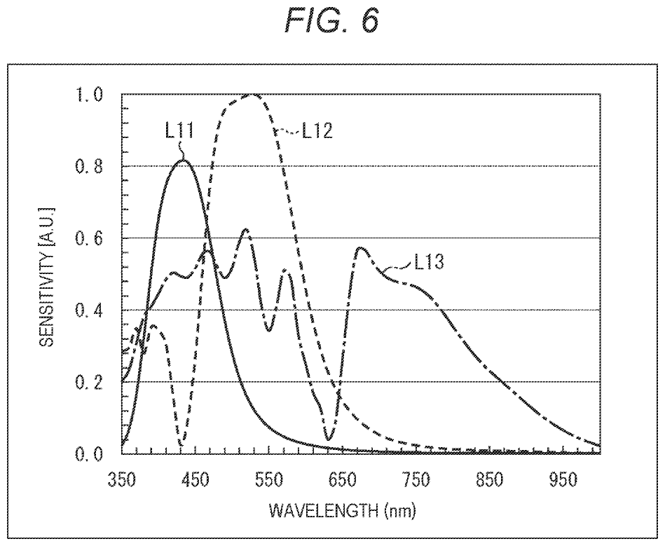

FIG. 6 is a graph illustrating an example of spectral characteristics of the plasmonic filter 121A in a case where the hole pitch P1 is changed. The horizontal axis of the graph represents wavelength (nm), and the vertical axis represents sensitivity (arbitrary unit). Line L11 indicates spectral characteristics in a case where the hole pitch P1 is set to 250 nm, line L12 indicates spectral characteristics in a case where the hole pitch P1 is set to 325 nm, and line L13 indicates spectral characteristics in a case where the hole pitch P1 is set to 500 nm.

In the case where the hole pitch P1 is set to 250 nm, the plasmonic filter 121A mainly transmits light in a blue wavelength band. In the case where the hole pitch P1 is set to 325 nm, the plasmonic filter 121A mainly transmits light in a green wavelength band. In the case where the hole pitch P1 is set to 500 nm, the plasmonic filter 121A mainly transmits light in a red wavelength band. It is to be noted, however, that in the case where the hole pitch P1 is set to 500 nm, the plasmonic filter 121A also transmits a large amount of light in a band having a wavelength lower than that of red due to a waveguide mode.

<Example of Other Plasmonic Filters>

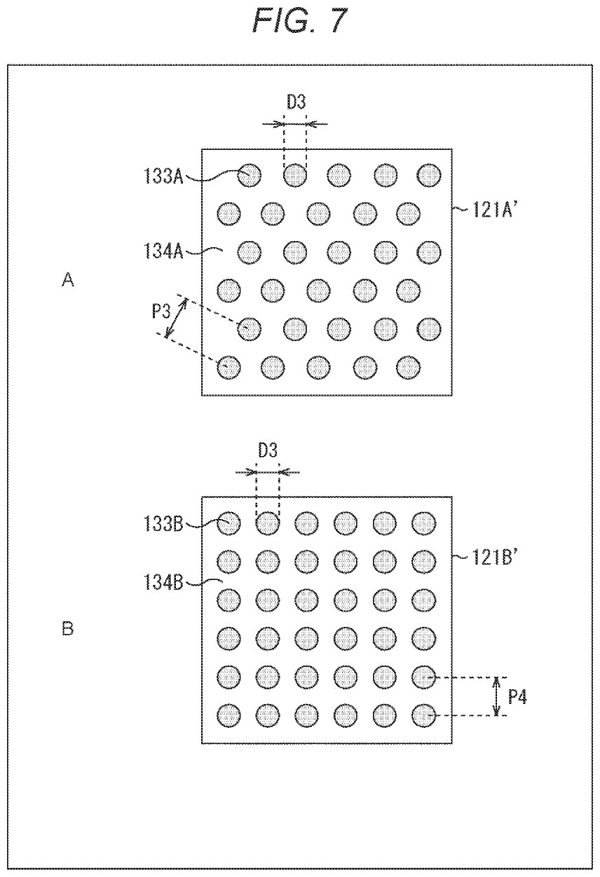

A plasmonic filter having a dot array structure (dot array type plasmonic filter) will be described with reference to FIG. 7.

A plasmonic filter 121A′ in A of FIG. 7 has a structure obtained by negative-positive inverting the plasmonic resonator of the plasmonic filter 121A in FIG. 4, that is, includes a plasmonic resonator in which dots 133A are arranged in a honeycomb shape in a dielectric layer 134A. The dielectric layer 134A is filled between the dots 133A.

The plasmonic filter 121A′ is used as a complementary color filter to absorb light in a predetermined wavelength band. The wavelength band (hereinafter referred to as absorption band) of the light absorbed by the plasmonic filter 121A′ changes depending on the pitch (hereinafter referred to as dot pitch) P3 between the adjacent dots 133A, and the like. Furthermore, a diameter D3 of the dot 133A is adjusted in accordance with the dot pitch P3.

A plasmonic filter 121B′ in B of FIG. 7 has a plasmonic resonator structure in which dots 133B are arranged in an orthogonal matrix in a dielectric layer 134B. The dielectric layer 134B is filled between the dots 133B. The absorption band of the plasmonic filter 121B′ changes depending on a dot pitch P4 between adjacent dots 133B, and the like. Furthermore, the diameter D3 of the dot 133B is adjusted in accordance with the dot pitch P4.

As the dot pitch P3 narrows, the absorption band of the plasmonic filter 121A′ shifts to the short wavelength side, and as the dot pitch P3 widens, the absorption band of the plasmonic filter 121A′ shifts to the long wavelength side.

Note that in any plasmonic filter of the hole array structure and the dot array structure, the transmission band or the absorption band can be adjusted only by adjusting the pitch of the holes or dots in the planar direction. Therefore, for example, it is possible to individually set the transmission band or the absorption band for each pixel only by adjusting the pitch of the holes or the dots in the lithography process, and it is possible to multicolor the filter in fewer processes.

Furthermore, the thickness of the plasmonic filter is about 100 to 500 nm, which is substantially similar to that of the organic material-based color filter, and the plasmonic filter has good process affinity.

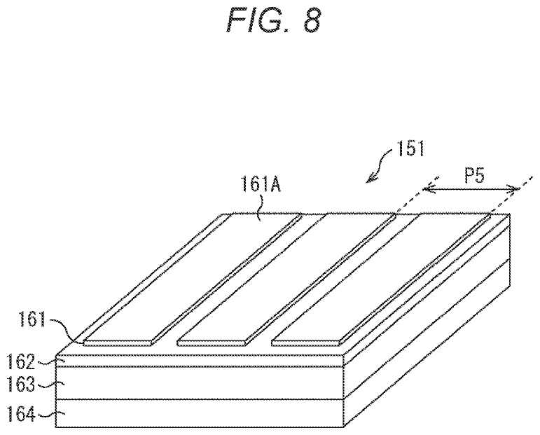

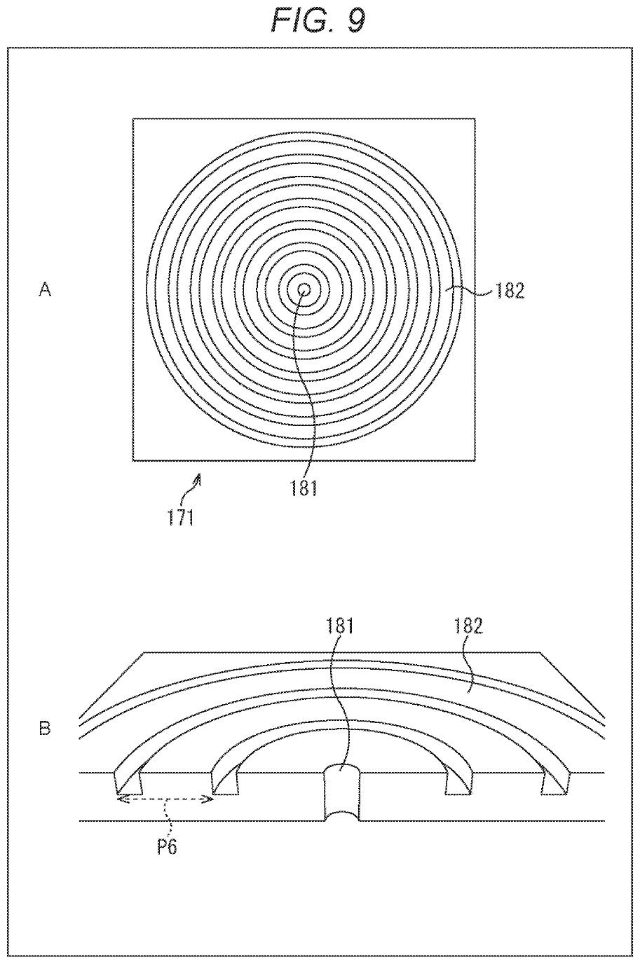

Furthermore, a plasmonic filter 151 using guided mode resonant (GMR) depicted in FIG. 8 can also be used as the narrow-band filter NB.

In the plasmonic filter 151, a conductor layer 161, an SiO2 film 162, an SiN film 163, and an SiO2 substrate 164 are laminated in this order from the top. The conductor layer 161 is included, for example, in the narrow-band filter layer 103 of FIG. 3, and the SiO2 film 162, the SiN film 163, and the SiO2 substrate 164 are included, for example, in the interlayer film 104 of FIG. 3.

On the conductor layer 161, rectangular conductor thin films 161A including, for example, aluminum are arranged at a predetermined pitch P5 such that long sides of the conductor thin films 161A are adjacent to each other. Then, the transmission band of the plasmonic filter 151 changes depending on the pitch P5, and the like. Specifically, as the pitch P5 narrows, the transmission band of the plasmonic filter 151 shifts to the short wavelength side, and as the pitch P5 widens, the transmission band of the plasmonic filter 151 shifts to the long wavelength side.

Similarly to the plasmonic filter having the hole array structure and the dot array structure described above, the plasmonic filter 151 using GMR also has good affinity with an organic material-based color filter.

As the plasmonic filter, for example, a filter having a shape called a bull's eye (hereinafter described as bull's-eye structure) can be applied as a shape other than the hole array structure, the dot array structure, and GMR described above. The bull's-eye structure is a name given because it is similar to a target of a dart game or a target of archery.

As depicted in A of FIG. 9, a plasmonic filter 171 having a bull's-eye structure has a through hole 181 at the center, and includes a plurality of protrusions 182 formed concentrically around the through hole 181. That is, the plasmonic filter 171 having a bull's-eye structure has a shape to which a diffraction grating structure of metal that causes plasmon resonance is applied.

The plasmonic filter 171 having a bull's-eye structure has characteristics similar to those of the plasmonic filter 151 of GMR. That is, in a case where a pitch P6 is set between the protrusions 182, the transmission band of the plasmonic filter 171 shifts to the short wavelength side as the pitch P6 narrows, and the transmission band of the plasmonic filter 171 shifts to the long wavelength side as the pitch P6 widens.

As the narrow-band filter NB applicable to the imaging device to which the present technology is applied, there are plasmonic filters such as the hole array structure, the dot array structure, GMR, and the bull's-eye structure described above.

In the following description, a case where the narrow-band filter NB is a plasmonic filter 121 having a hole array structure will be described as an example unless otherwise specified. However, a plasmonic filter having a dot array structure, GMR, a bull's-eye structure, or the like can also be applied, and the narrow-band filter NB can be appropriately replaced with a plasmonic filter having a dot array structure, a GMR, a bull's-eye structure, or the like.

<Configuration Example of Pixel Array Unit>

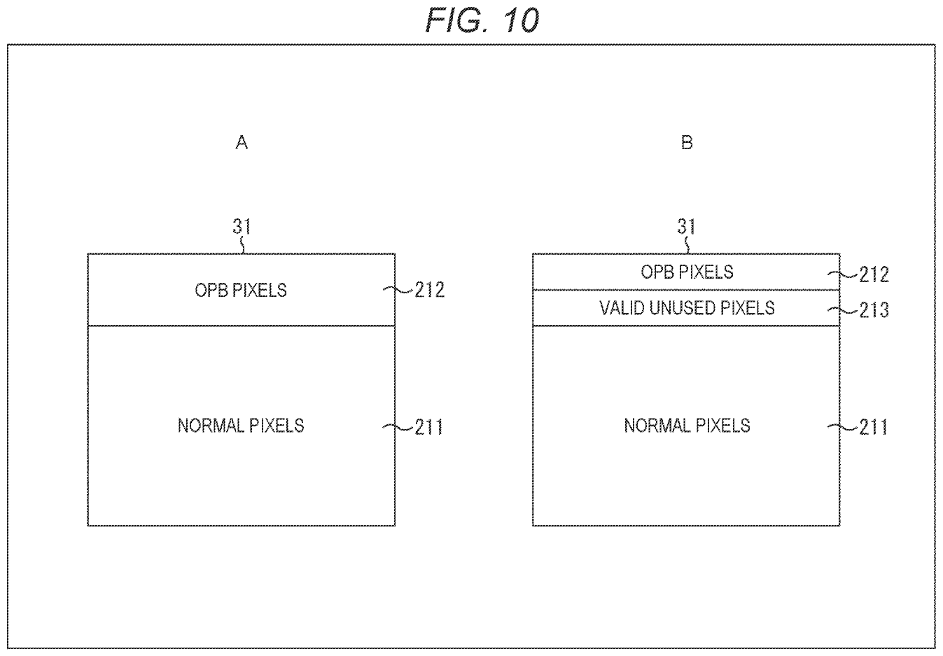

FIG. 10 is a diagram illustrating a planar configuration example of the pixel array unit 31 of the imaging device 10.

In the pixel array unit 31 depicted in A of FIG. 10, a normal pixel region 211 in which normal pixels are arranged and an optical black (OPB) pixel region 212 in which OPB pixels are arranged are arranged. The OPB pixel region 212 arranged at the upper end (in FIG. 10) of the pixel array unit 31 is a light shielding region shielding light so that light does not enter. The normal pixel region 211 is an open region that is not shielded from light.

In the normal pixel region 211 arranged in the open region, normal pixels (hereinafter described as normal pixels 211) from which pixel signals are read when an image is generated are arranged.

In the OPB pixel region 212 arranged in the upper light shielding region, OPB pixels (hereinafter described as OPB pixels 212) used for reading a black level signal which is a pixel signal indicating a black level of an image are arranged.

In the pixel array unit 31 depicted in B of FIG. 10, a valid unused pixel region 213 in which valid unused pixels 213 are arranged is provided between the normal pixel region 211 and the OPB pixel region 212. The valid unused pixel region 213 is a region in which the valid unused pixels 213 whose read pixel signals are not used to generate an image are arranged. The valid unused pixel 213 mainly plays a role of ensuring uniformity of the characteristics of the pixel signals of the normal pixels 211.

The present technology described below can be applied to both of the pixel array units 31 depicted in A of FIGS. 10 and B of FIG. 10. Furthermore, the present technology described below can be applied to an arrangement other than the arrangements of the pixel array units 31 depicted in A of FIGS. 10 and B of FIG. 10.

For example, while the OPB pixel region 212 is formed on one side of the normal pixel region 211 in the example, the OPB pixel region may be provided on two to four sides. Furthermore, while the valid unused pixels 213 are formed on one side of the normal pixel region 211 in the example, the valid unused pixels may also be provided on two to four sides.

Note that the OPB pixel 212 and the valid unused pixel 213 can also be referred to as dummy pixels. The OPB pixel 212 and the valid unused pixel 213 are pixels whose read pixel signals are not used to generate an image. The fact that the read pixel signal is not used for generating an image means that the pixel is not displayed on a reproduced screen.

The OPB pixel 212 and the valid unused pixel 213 have a configuration similar to that of the normal pixel 211, and can be, for example, a pixel having a cross-sectional configuration example like the pixel 51 depicted in FIG. 3. As in the pixel 51 depicted in FIG. 3, the OPB pixel 212 may also include the on-chip lens 101, but the configuration of the OPB pixel 212 and the valid unused pixel 213 (dummy pixel) may omit the on-chip lens 101. Furthermore, the on-chip lens 101 may be in a state in which the light condensing function is deteriorated, such as being crushed.

Furthermore, the dummy pixels do not need to be connected by the vertical signal line V (FIG. 2) in plan view.

Furthermore, the dummy pixel does not need to include a transistor equivalent to the transistor included in the valid pixel (normal pixel 211). The transistors included in the pixel 51 (corresponding to normal pixel 211) have been described in FIG. 2. While the normal pixel 211 includes a plurality of transistors, a pixel including fewer transistors than the plurality of transistors included in the normal pixel 211 may be used as a dummy pixel.

As described above, the dummy pixel has a configuration different from that of the normal pixel 211, and, for example, at least one of the elements (transistors, FD, OCL, and the like) of the normal pixel 211 may have a different configuration.

Hereinbelow, the description will be continued on the assumption that the configuration of the OPB pixel 212 is basically similar to that of the normal pixel 211. Furthermore, hereinbelow, the description will be continued by taking the OPB pixel region 212 as an example. However, the OPB pixel region 212 in the following description may include the valid unused pixel region 213.

In the following description, the normal pixel region 211 is a valid pixel region, and is a region in which the normal pixels 211 are arranged. The OPB pixel region 212 is an invalid pixel region, and is a region in which dummy pixels are arranged. A PAD region 301 is also an invalid pixel region, and may be a region in which dummy pixels are arranged or a region in which no pixels are arranged.

<Cross-Sectional Configuration of Pixel Array Unit>

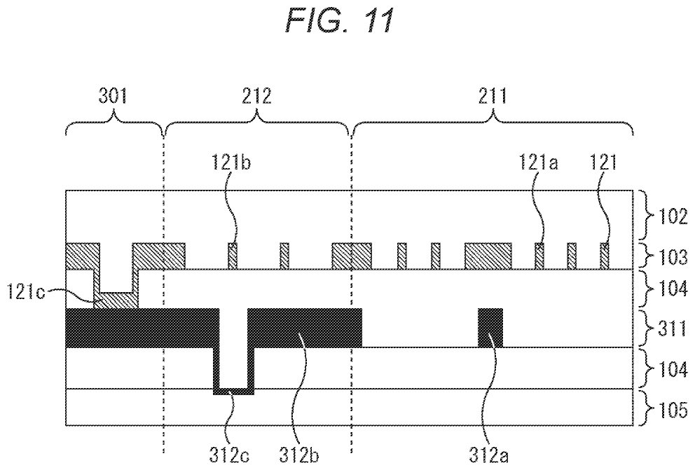

FIG. 11 is a diagram illustrating a cross-sectional configuration example of the pixel array unit 31. FIG. 11 illustrates a cross-sectional configuration example of the normal pixel region 211, the OPB pixel region 212, and the PAD region 301. In FIG. 11, in order to mainly describe a cross-sectional configuration example of the plasmonic filter formed in the narrow-band filter layer 103, other parts are appropriately omitted.

In the cross-sectional configuration example of the pixel array unit 31 depicted in FIG. 11, an example in which an OPB layer 311 is provided in the interlayer film 104 is depicted. In the OPB layer 311, a light shielding member 312 including a material having a high light shielding property such as metal is formed. A light shielding member 312a formed in the OPB layer 311 of the normal pixel region 211 functions as a light shielding wall that prevents light from leaking into the adjacent pixels 51, and is formed between the adjacent pixels 51.

The OPB layer 311 is laminated on the light incident surface side of the photoelectric conversion element layer 105. The narrow-band filter layer 103 is then laminated on the light incident surface side of the OPB layer 311. In the photoelectric conversion element layer 105, the normal pixel region 211 includes the normal pixel 211, and the OPB region 212 includes a dummy pixel. The OPB layer 311 and the narrow-band filter layer 103 are laminated on such a semiconductor layer of the photoelectric conversion element layer 105 including the normal pixel 211 and the dummy pixel.

In the OPB pixel region 212, a light shielding member 312b that functions as a light shielding film that shields incident light is formed to function as the OPB pixel 212. The light shielding member 312b is also formed in the PAD region 301.

The PAD region 301 is a region in which an electrode pad for connecting to another substrate is arranged. The PAD region 301 may include a scribe region or the like.

Apart of the light shielding member 312b is a light shielding member 312c formed in a recessed shape so as to be connected to (the substrate of) the laminated photoelectric conversion element layer 105. Since the light shielding member 312c is connected to the substrate, the light shielding member 312b is also connected to the substrate. Since the light shielding member 312a is formed so as to surround the pixel 51, the light shielding member 312a and the light shielding member 312b are connected.

Therefore, the light shielding member 312 is in contact with the substrate. With such a configuration, occurrence of arcing in the light shielding member 312 can be curbed.

For example, in order to curb the occurrence of arcing during processing, the light shielding member 312c functions as a contact in contact with a substrate serving as a ground so that the light shielding member 312 including metal does not float. Hereinafter, the light shielding member 312c in contact with the substrate will be appropriately referred to as a grounding part.

Similarly, since the plasmonic filter 121 formed in the narrow-band filter layer 103 also includes metal such as aluminum, arcing may occur. A part of the plasmonic filter 121 formed in the narrow-band filter layer 103 is a plasmonic filter 121c formed in a recessed shape so as to be connected to the light shielding member 312. FIG. 11 illustrates an example in which the plasmonic filter 121c is formed in the PAD region 301.

Here, while the description will be continued using the term “plasmonic filter 121c”, the plasmonic filters 121b and 121c provided in the OPB pixel region 212 and the PAD region 301 do not need to have a function as a filter. The description will be continued on the assumption that the plasmonic filters 121b and 121c are metal films including metal and integrally formed with the plasmonic filter 121a. An integrally formed metal film is a metal film at least partially connected to the plasmonic filter 121a provided in the normal pixel region 211. Here, such a metal film is described as plasmonic filters 121b and 121c, and the description will be continued.

Since the plasmonic filter 121c formed in the PAD region 301 is connected to the light shielding member 312, the entire plasmonic filter 121 is also connected to the light shielding member 312. As described above, since the light shielding member 312 is grounded, the plasmonic filter 121 is also grounded. With such a configuration, occurrence of arcing in the plasmonic filter 121 can be curbed.

In a case where arcing occurs in the light shielding member 312 and charge is generated, the light shielding member 312c is formed as an escape path of the charge, so that even in a case where arcing occurs, the influence can be reduced.

Similarly, in a case where arcing occurs in the plasmonic filter 121 and charge is generated, the plasmonic filter 121c is formed as an escape path of the charge. Since the plasmonic filter 121c is in contact with the light shielding member 312, even in a case where arcing occurs, the influence can be reduced. Hereinafter, the plasmonic filter 121c in contact with the light shielding member 312 will be appropriately referred to as a grounding part.

The light shielding member 312 can be in contact with the substrate via a barrier metal. In other words, a barrier metal may be laminated on the light shielding member 312. By laminating the barrier metal on the light shielding member 312, for example, hydrogen generated at the time of processing can be occluded in the barrier metal, and generation of blisters can be curbed.

On the other hand, in a case where the barrier metal is laminated on the plasmonic filter 121, the propagation characteristic of the plasmonic filter 121 is deteriorated, and the performance of the plasmonic filter 121 is deteriorated. Therefore, it is not preferable to laminate the barrier metal on the plasmonic filter 121.

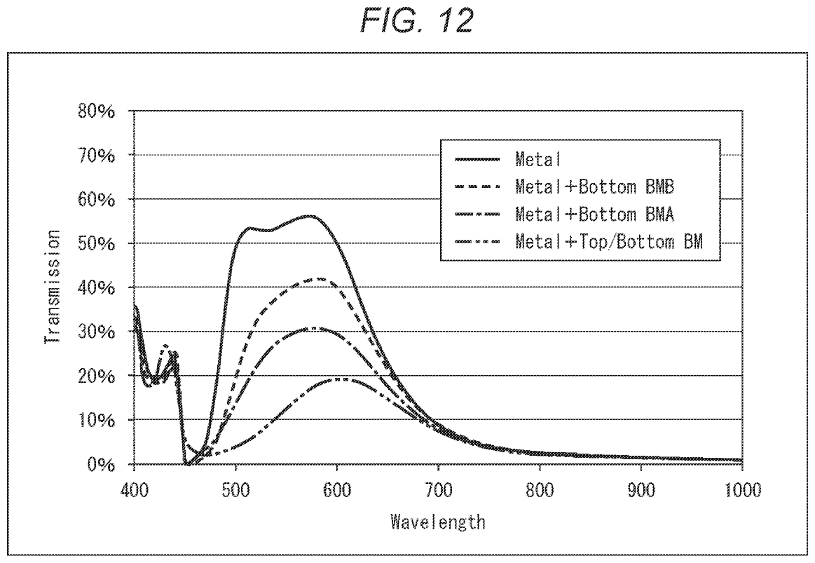

FIG. 12 is a graph illustrating the propagation intensity in a case where a barrier metal is added to a metal film, and is a graph in which the horizontal axis represents frequency and the vertical axis represents propagation intensity. Here, the description will be continued on the assumption that the metal film is the plasmonic filter 121.

In FIG. 12, a two-dot chain line graph is a graph illustrating the propagation intensity in a case where a barrier metal is laminated on an upper surface and a lower surface of the plasmonic filter 121. In FIG. 12, a one-dot chain line graph is a graph illustrating the propagation intensity in a case where a barrier metal of a material A is laminated on the lower surface of the plasmonic filter 121.

In FIG. 12, a dotted line graph is a graph illustrating the propagation intensity in a case where a barrier metal of a material B is laminated on the lower surface of the plasmonic filter 121. In FIG. 12, a solid line graph is a graph illustrating the propagation intensity in the case of only the plasmonic filter 121.

From the graph depicted in FIG. 12, it can be seen that the propagation intensity decreases at any frequency by laminating the barrier metal on the plasmonic filter 121. From this result, it can be understood that in a case where the barrier metal is laminated on the plasmonic filter 121, there is a possibility that the propagation intensity of the plasmonic filter 121 decreases, the light transmitted through the plasmonic filter 121 decreases, and the sensitivity decreases, and therefore, a configuration in which no barrier metal is laminated on the plasmonic filter 121 is preferable.

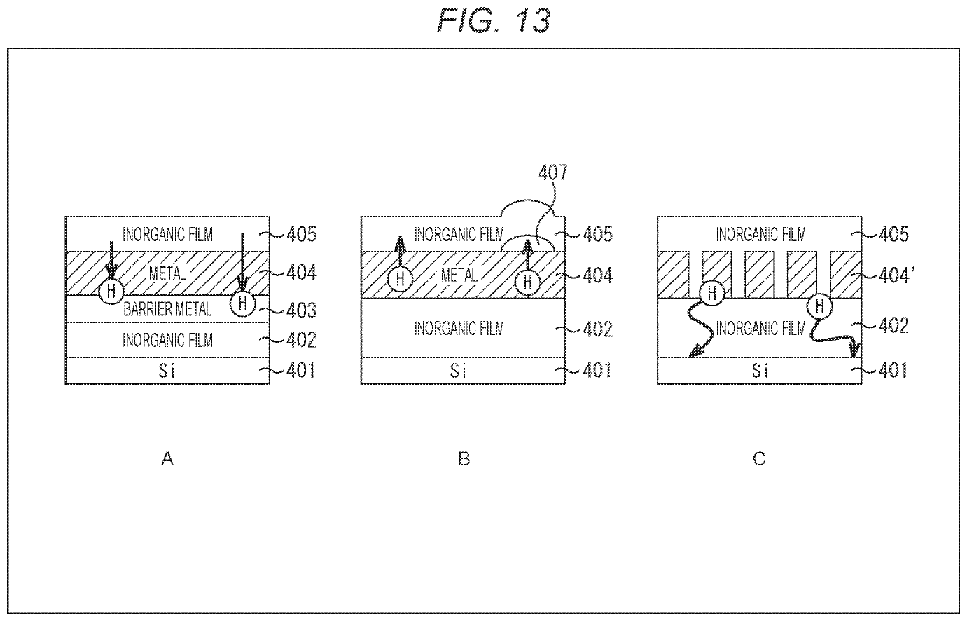

If no barrier metal is laminated, blisters may occur, and the performance of the image pickup element may be deteriorated due to the blisters. This point will be described with reference to FIG. 13.

The laminated structure depicted in A of FIG. 13 is a structure in a case where a barrier metal is laminated on a metal film. In the laminated structure depicted in A of FIG. 13, an inorganic film 402 is laminated on a silicon (Si) substrate 401, and a barrier metal 403 is laminated on the inorganic film 402. A metal film 404 is laminated on the barrier metal 403, and an inorganic film 405 is laminated on the metal film 404.

In a case where a Ti-based metal that occludes hydrogen is used as the barrier metal 403, for example, even when hydrogen is generated by applying heat during processing, hydrogen is occluded in the barrier metal 403, so that it is possible to prevent diffusion of hydrogen.

As in B of FIG. 13, in a case where the barrier metal 403 is not laminated, blisters may occur between the metal film and the inorganic film where adhesion is low. The laminated structure depicted in B of FIG. 13 has a structure in which the silicon substrate 401, the inorganic film 402, the metal film 404, and the inorganic film 405 are laminated in this order from the bottom in B of FIG. 13, and has a structure in which the barrier metal 403 is not laminated.

For example, the metal film 404 and the inorganic film 405 are parts where adhesion tends to be low, and, for example, in a case where hydrogen is generated by applying heat during processing, hydrogen moves to the part where adhesion is low, and a blister 407 may occur.

By adopting the laminated structure as depicted in C of FIG. 13, it is possible to reduce the occurrence of blisters without providing the barrier metal 403. The laminated structure depicted in C of FIG. 13 is the same as the laminated structure depicted in B of FIG. 13, but the configuration of the metal film 404 is different. A metal film 404′ depicted in C of FIG. 13 is formed in a partially penetrated state, and the penetrated parts are filled with the same inorganic substance as the inorganic films 402 and 405. The inorganic film 402 and the inorganic film 405 are connected by through holes provided in the metal film 404′.

As described above, by providing through holes in parts of the metal film 404, the through holes serve as escape paths for hydrogen, and the occurrence of blisters can be curbed. The metal film 404′ corresponds to the plasmonic filter 121. The configuration in C of FIG. 13 is a configuration in which the narrow-band filter layer 103 including the plasmonic filter 121 corresponding to the metal film 404′ is laminated between the interlayer film 104 corresponding to the inorganic film 402 and the interlayer film 102 corresponding to the inorganic film 405, as in the case of the laminated structure depicted in FIG. 11.

As described with reference to FIG. 4, the plasmonic filter 121 has the hole 132A, and the hole 132A is a through hole. Therefore, the plasmonic filter 121 arranged in the normal pixel region 211 can curb the occurrence of blisters even with a configuration with no barrier metal.

The cross-sectional configuration example of the pixel array unit 31 depicted in FIG. 11 will be referred to again. The plasmonic filter 121 is also provided in the OPB pixel region 212 and the PAD region 301. The plasmonic filter 121 does not need to function as a filter, and is included to provide a grounding part (plasmonic filter 121c) for curbing occurrence of arcing.

Since the plasmonic filter 121 provided in the OPB pixel region 212 and the PAD region 301 does not need to have a function as a filter, the hole 132A may be omitted. However, a through hole corresponding to the hole 132A is provided in order to curb occurrence of blisters. That is, the configuration of the plasmonic filter 121 is similar to that of the plasmonic filter 121a provided in the normal pixel region 211.

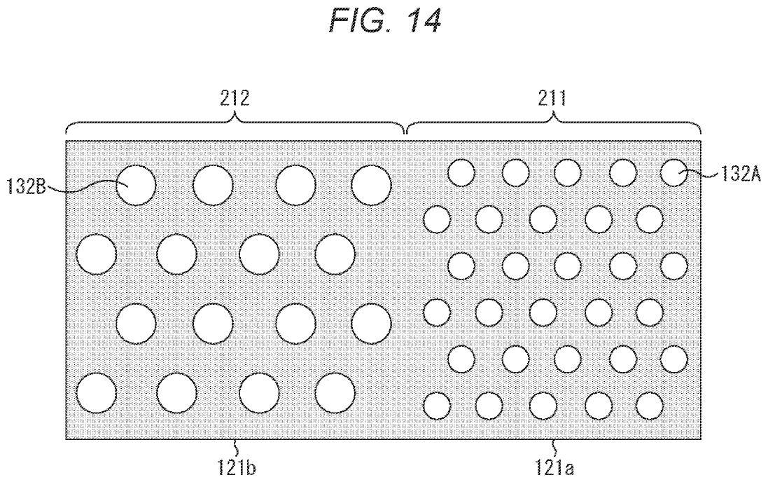

FIG. 14 illustrates a planar configuration example of the plasmonic filter 121 arranged in the normal pixel region 211 and the OPB pixel region 212. As described with reference to FIG. 4, in the plasmonic filter 121a arranged in the normal pixel region 211, the size and arrangement of the holes 132A are determined according to the frequency desired to be transmitted.

A hole 132B of the plasmonic filter 121b arranged in the OPB pixel region 212 is formed to be larger than the hole 132A of the plasmonic filter 121a arranged in the normal pixel region 211. Since the plasmonic filter 121b does not need to function as a filter, the shape, size, arrangement position, and the like of the hole 132B can be freely set.

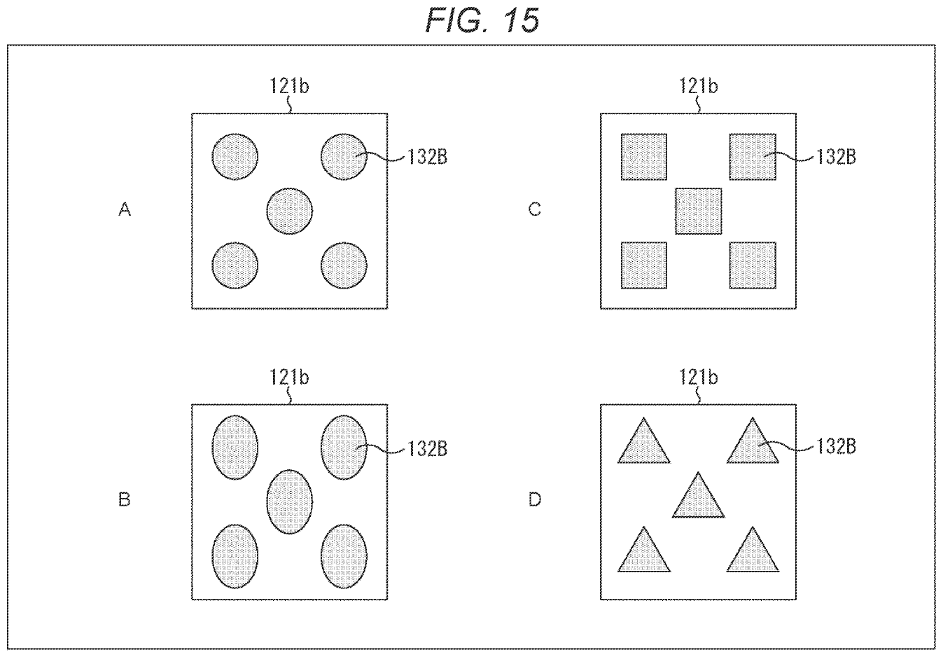

For example, the shape of the hole 132B may be a circular shape as depicted in A of FIG. 15, or may be an elliptical shape as depicted in B of FIG. 15. The shape of the hole 132B may be a rectangular shape as depicted in C of FIG. 15, or may be a triangular shape as depicted in D of FIG. 15. Although not depicted, the shape of the hole 132B may be a polygonal shape.

The shapes of the holes 132B may all be the same or may be different. That is, as the shapes of the holes 132B, for example, circular holes 132B depicted in A of FIG. 15 and rectangular holes 132B depicted in C of FIG. 15 may be mixed. Furthermore, for example, regarding the circular holes 132B depicted in A of FIG. 15, circular holes 132B having different sizes may be mixed.

The size of the hole 132B should be formed as large as possible to curb blisters even more. Even if the size of one hole 132B is formed small, many holes 132B may be formed so that the opening part becomes large as a result.

The shape and size of the hole 132B of the plasmonic filter 121b formed in the OPB pixel region 212 may be formed similar to those of the plasmonic filter 121a formed in the normal pixel region 211.

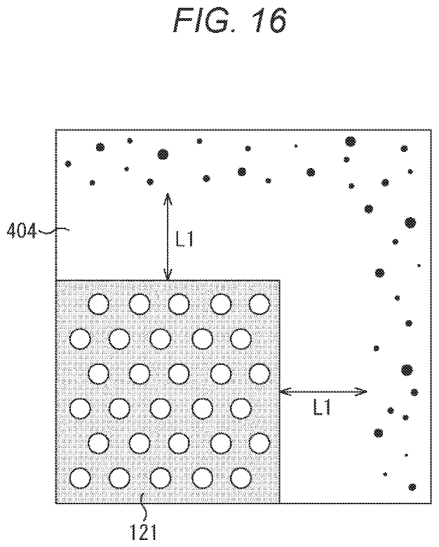

The holes 132B are arranged such that the distance between the holes 132B is 100 um or less, for example. Setting the distance between the holes 132B to 100 um or less will be described with reference to FIG. 16. The present applicant observed the positions where blisters occur when the plasmonic filter 121 and the metal film 404 having no holes 132A provided therearound are used.

As a result, as depicted in FIG. 16, blisters occurred at positions separated from the plasmonic filter 121 by a distance L1 or more. In other words, it has been confirmed that no blister occurs when the distance from a side of the plasmonic filter 121 is within the distance L1. The distance L1 was about 100 um.

On the basis of such a result, it can be estimated that when the region of the metal film having no holes (through holes) is equal to or longer than the distance L1, the possibility of blister occurrence increases. That is, when the interval between the holes 132B is 100 um or more, it can be estimated that blisters may occur. Therefore, as described above, the arrangement position of the holes 132B is determined such that the interval between the holes 132B is 100 um or less.

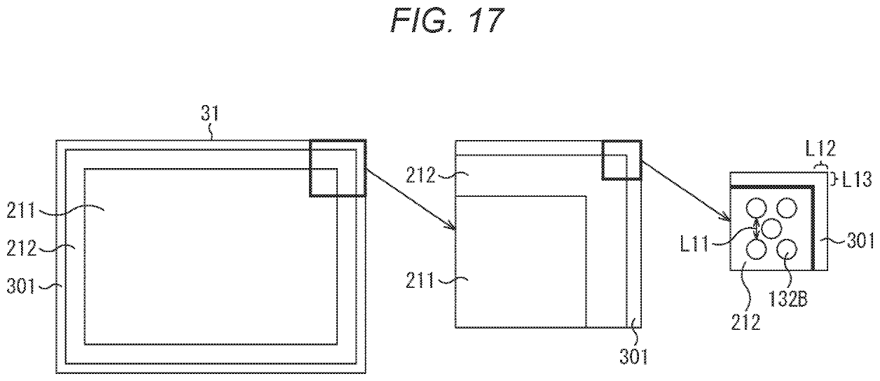

FIG. 17 is an enlarged view of the pixel array unit 31 and a part thereof, and is a view for describing an interval between the holes 132B in the enlarged view. As depicted on the left side of FIG. 17, in the pixel array unit 31, the normal pixel region 211 is arranged at the center, the OPB pixel region 212 is arranged around the normal pixel region 211, and the PAD region 301 is arranged around the OPB pixel region 212.

The upper right part of the pixel array unit 31 in FIG. 17 is enlarged in the diagram depicted at the center of FIG. 17, and the upper right part is further enlarged in the diagram depicted on the right of FIG. 17. Referring to the right diagram in FIG. 17, the plasmonic filter 121b is formed in the OPB pixel region 212, and the holes 132B are formed in the plasmonic filter 121b. When attention is paid to a predetermined hole 132B, the hole 132B is arranged at a position where a distance L11 between the hole 132B and the adjacent hole 132B is 100 um or less.

In a case where the plasmonic filter 121 is provided to extend to the PAD region 301, and in a case where the hole 132B is not formed in the plasmonic filter 121 arranged in the PAD region 301, the region where the hole 132B is not formed is within a distance L12 and a distance L13. The distance L12 and the distance L13 are also 100 um or less.

In this way, the region where the hole 132 is not formed is set to be within a size of 100 um or less, whereby the occurrence of blisters can be curbed.

<Other Configuration of Pixel Array Unit>

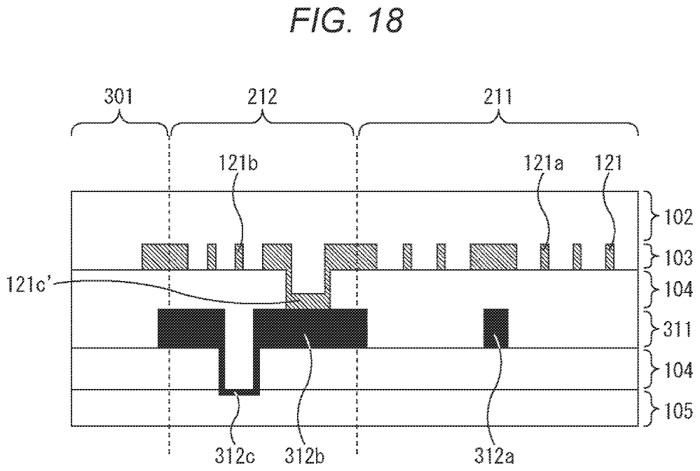

FIG. 18 is a diagram illustrating another cross-sectional configuration example of the pixel array unit 31. Parts similar to those in the cross-sectional configuration example of the pixel array unit 31 depicted in FIG. 11 are denoted by the same reference numerals, and description thereof will be omitted.

In the pixel array unit 31 depicted in FIG. 18, the position of the plasmonic filter 121c functioning as the grounding part of the plasmonic filter 121 formed in the narrow-band filter layer 103 is different from that of the pixel array unit 31 depicted in FIG. 11. A plasmonic filter 121c′ functioning as a grounding part of the plasmonic filter 121 of the pixel array unit 31 depicted in FIG. 18 is formed in the OPB pixel region 212.

The plasmonic filter 121c′ functioning as the grounding part may be provided in the PAD region 301 as in the pixel array unit 31 depicted in FIG. 11, or may be provided in the OPB pixel region 212 as in the pixel array unit 31 depicted in FIG. 18. A plurality of plasmonic filters 121c functioning as the grounding part may be provided, and may be provided in each of the OPB pixel region 212 and the PAD region 301.

By providing the grounding part in the plasmonic filter 121, occurrence of arcing can be curbed. The grounding part is arranged in a region in which the plasmonic filter 121 does not need to function as a filter, that is, an invalid pixel region such as the OPB pixel region 212 or the PAD region 301.

In order to provide the grounding part in an invalid pixel region such as the OPB pixel region 212 or the PAD region 301, the plasmonic filter 121 is formed to extend from the normal pixel region 211 to the OPB pixel region 212 or the PAD region 301.

The plasmonic filter 121 provided in the OPB pixel region 212 or the PAD region 301 has through holes corresponding to the holes 132, so that the occurrence of blisters can be curbed.

As described above, by providing the holes (through holes) in the plasmonic filter 121 formed in the OPB pixel region 212 and the PAD region 301 (invalid pixel region) similarly to the normal pixel region 211 (valid pixel region), the difference in aperture ratio between the plasmonic filter 121 in the valid pixel region and the plasmonic filter 121 in the invalid pixel region is reduced, so that the shape stability of the end part of the valid pixel region can be improved.

In the above-described embodiment, the plasmonic filter 121 having a hole array structure has been described as an example, but a plasmonic filter having a dot array structure, GMR, a bull's-eye structure, or the like can also be applied. In a case where a plasmonic filter having a dot array structure, GMR, a bull's-eye structure, or the like is applied, the metal film formed in the invalid pixel region of the OPB pixel region 212 or the PAD region 301 may have a structure equivalent to or different from the structure of the filter applied as the plasmonic filter.

For example, in a case where a plasmonic filter having a dot array structure is applied, the metal film formed in the invalid pixel region may also be configured such that a part corresponding to the dot is used as a through hole, or a through hole having a shape other than the dot, such as a quadrangular shape, may be formed.

The present technology is also applicable to devices other than the image pickup element 12 described above. For example, the present invention is also applicable to a distance measuring device that performs distance measurement.

<Example of Application to Endoscopic Surgery System>

The technology of the present disclosure (present technology) can be applied to various products. For example, the technology of the present disclosure may be applied to an endoscopic surgery system.

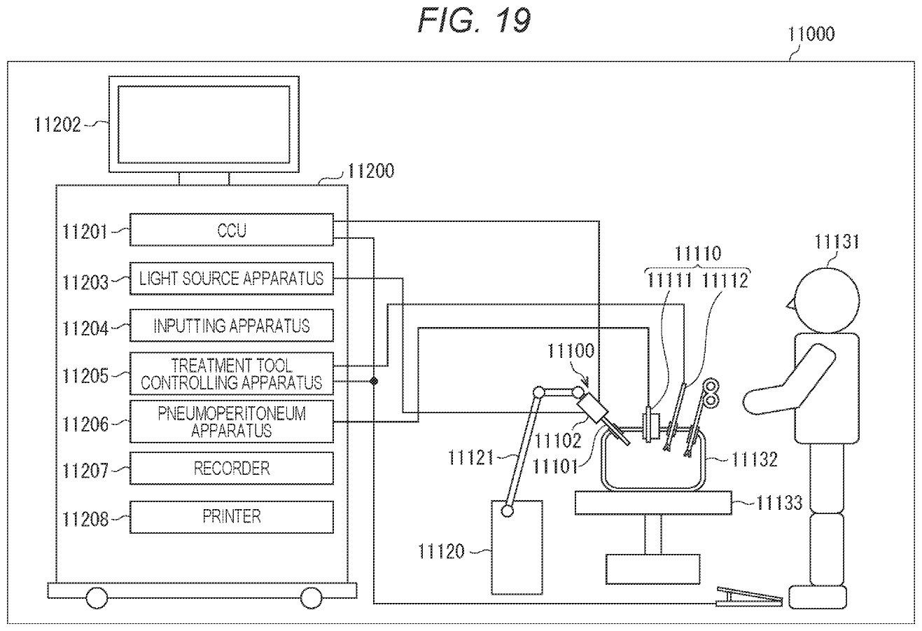

FIG. 19 is a view depicting an example of a schematic configuration of an endoscopic surgery system to which the technology of the present disclosure (present technology) can be applied.

In FIG. 19, a state is depicted in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. Alight source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

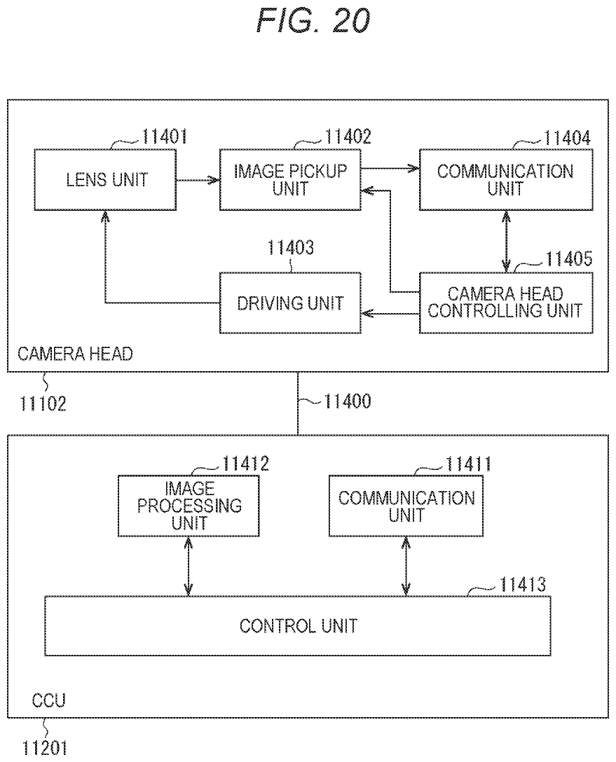

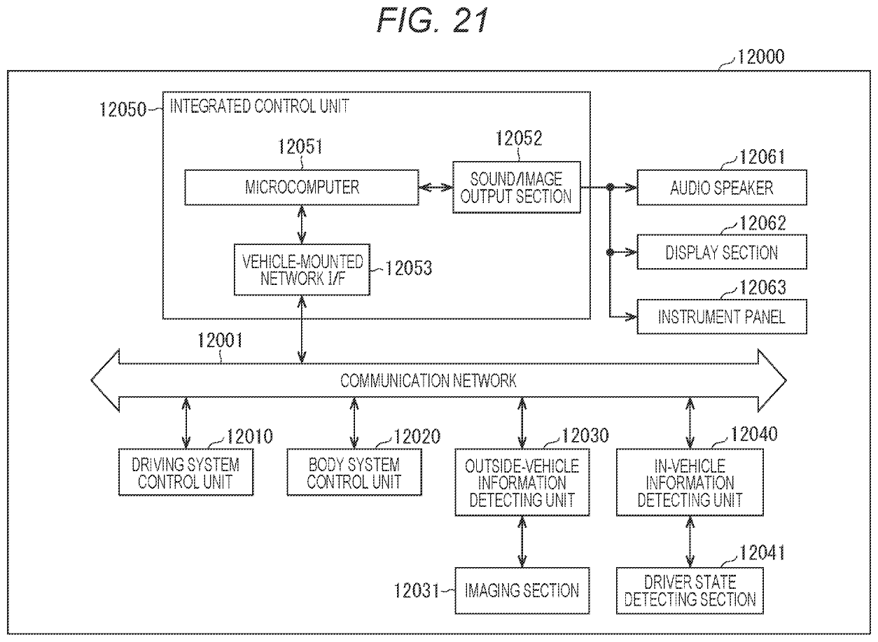

FIG. 20 is a block diagram illustrating an example of a functional configuration of the camera head 11102 and the CCU 11201 depicted in FIG. 19.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

<Example of Application to Movable Body>

The technology of the present disclosure (present technology) can be applied to various products. For example, the technology of the present disclosure may be implemented as a device mounted on any of types of movable bodies such as a car, an electric car, a hybrid electric car, a motorcycle, a bicycle, a personal mobility, an airplane, a drone, a ship, a robot, and the like.

FIG. 21 is a block diagram depicting an example of a schematic configuration of a vehicle control system as an example of a movable body control system to which the technology of the present disclosure can be applied.

The vehicle control system 12000 includes a plurality of electronic control units connected to each other via a communication network 12001. In the example depicted in FIG. 21, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 21, an audio speaker 12061, a display section 12062, and an instrument panel 12063 are illustrated as the output device. The display section 12062 may, for example, include at least one of an on-board display and a head-up display.

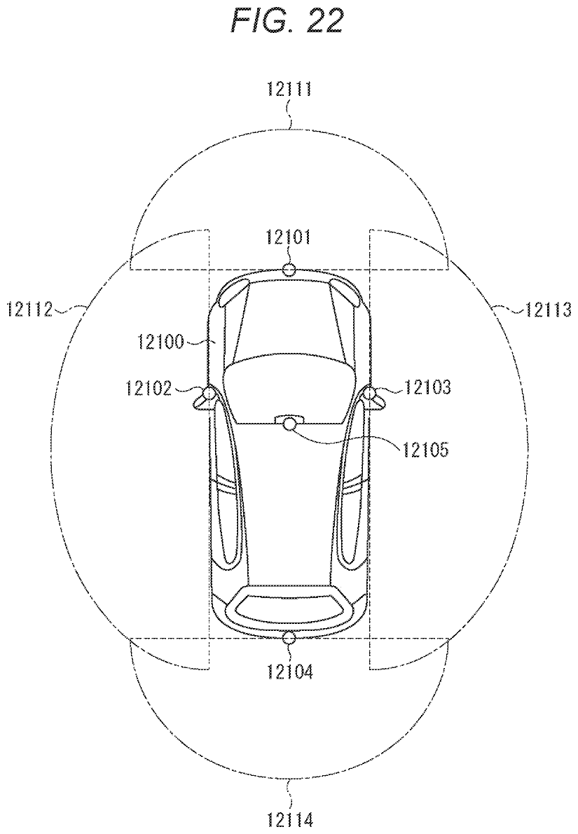

FIG. 22 is a diagram depicting an example of the installation positions of the imaging section 12031.

In FIG. 22, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 22 depicts an example of image capturing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the present specification, the system represents the entire device including a plurality of devices.

Note that the effect described in the present specification is merely an illustration and is not restrictive. Hence, other effects can be obtained.

Note that the embodiment of the present technology is not limited to the above-described embodiment, and various modifications can be made without departing from the scope of the present technology.

Note that the present technology can also be configured in the following manner.

(1)

An image pickup element including:
a semiconductor layer in which
a first region where a first pixel in which a read pixel signal is used to generate an image is arranged and
a second region where a second pixel in which a read pixel signal is not used to generate an image is arranged
are arranged;
a narrow-band filter that is laminated on the first region on a light incident surface side of the semiconductor layer and transmits light of a desired wavelength; and
a metal film that is laminated on the second region on the light incident surface side of the semiconductor layer and has a plurality of through holes.

(2)

The image pickup element according to (1) above, in which
the narrow-band filter and the metal film are arranged in the same layer and connected to each other.

(3)

The image pickup element according to (1) or (2) above, in which
a shape of the through hole is any of a circular shape, a rectangular shape, and a polygonal shape.

(4)

The image pickup element according to any one of (1) to (3) above, in which
a distance between the through holes is 100 um or less.

(5)

The image pickup element according to any one of (1) to (4) above, in which
the narrow-band filter has a through hole, and the through hole of the metal film is larger than the through hole of the narrow-band filter.

(6)

The image pickup element according to any one of (1) to (5) above, in which
the metal film is grounded.

(7)

The image pickup element according to any one of (1) to (6) above, in which
the second region includes an optical black (OPB) region.

(8)

The image pickup element according to any one of (1) to (7) above further including a light shielding film laminated between the semiconductor layer and the metal film and including a light shielding member, in which
a part of the metal film is connected to the light shielding member.

(9)

The image pickup element according to any one of (1) to (8) above, in which
the second region includes a region where an electrode pad is formed, and
the metal film is grounded in the region where the electrode pad is formed.

(10)

The image pickup element according to any one of (1) to (9) above, in which
the narrow-band filter includes a hole array type plasmonic filter.

(11)

The image pickup element according to any one of (1) to (9) above, in which
the narrow-band filter includes a dot array type plasmonic filter.

(12)

The image pickup element according to any one of (1) to (9) above, in which
the narrow-band filter includes a plasmonic filter using guided mode resonant (GMR).

(13)

The image pickup element according to any one of (1) to (9) above, in which
the narrow-band filter includes a plasmonic filter having a bull's-eye structure.

(14)

An electronic device including:
an image pickup element having
a semiconductor layer in which
a first region where a first pixel in which a read pixel signal is used to generate an image is arranged and
a second region where a second pixel in which a read pixel signal is not used to generate an image is arranged
are arranged,
a narrow-band filter that is laminated on the first region on a light incident surface side of the semiconductor layer and transmits light of a desired wavelength, and
a metal film that is laminated on the second region on the light incident surface side of the semiconductor layer and has a plurality of through holes; and
a processing unit that processes a signal from the image pickup element.

### REFERENCE SIGNS LIST

Imaging device
11 Optical system
12 Image pickup element
13 Memory
14 Signal processing unit
15 Output unit
16 Control unit
31 Pixel array unit
32 Row scanning circuit
33 PLL
35 Column ADC circuit
36 Column scanning circuit
37 Sense amplifier
40 Inorganic film
51 Pixel
61 Photodiode
62 Transfer transistor
63 Floating diffusion
64 Amplification transistor
65 Selection transistor
66 Reset transistor
71 Comparator
72 Counter
101 On-chip lens
102 Interlayer film
103 Narrow-band filter layer
104 Interlayer film
105 Photoelectric conversion element layer
106 Wiring layer
121 Plasmonic filter
132 Hole
151 Plasmonic filter
161 Conductor layer
162 SiO2 film
163 SiN film
164 SiO2 substrate
171 Plasmonic filter
181 Through hole
182 Protrusion
211 Normal pixel region
212 OPB pixel region
213 Valid unused pixel region
301 PAD region
311 OPB layer
312 Light shielding member
401 Silicon substrate
402 Inorganic film
403 Barrier metal
404 Metal film
404′:Metal film
405 Inorganic film
407 Blister

What is claimed is:

1. An image pickup element, comprising:
a semiconductor layer in which
a first region where a first pixel in which a read pixel signal is used to generate an image is arranged and
a second region where a second pixel in which a read pixel signal is not used to generate an image is arranged
are arranged;
a narrow-band filter that is laminated on the first region on a light incident surface side of the semiconductor layer and transmits light of a desired wavelength; and
a metal film that is laminated on the second region on the light incident surface side of the semiconductor layer and has a plurality of through holes.

2. The image pickup element according to claim 1, wherein
the narrow-band filter and the metal film are arranged in the same layer and connected to each other.

3. The image pickup element according to claim 1, wherein
a shape of the through hole is any of a circular shape, a rectangular shape, and a polygonal shape.

4. The image pickup element according to claim 1, wherein
a distance between the through holes is 100 um or less.

5. The image pickup element according to claim 1, wherein
the narrow-band filter has a through hole, and the through hole of the metal film is larger than the through hole of the narrow-band filter.

6. The image pickup element according to claim 1, wherein
the metal film is grounded.

7. The image pickup element according to claim 1, wherein
the second region includes an optical black (OPB) region.

8. The image pickup element according to claim 1 further comprising a light shielding film laminated between the semiconductor layer and the metal film and including a light shielding member, wherein
a part of the metal film is connected to the light shielding member.

9. The image pickup element according to claim 1, wherein
the second region includes a region where an electrode pad is formed, and
the metal film is grounded in the region where the electrode pad is formed.

10. The image pickup element according to claim 1, wherein
the narrow-band filter includes a hole array type plasmonic filter.

11. The image pickup element according to claim 1, wherein
the narrow-band filter includes a dot array type plasmonic filter.

12. The image pickup element according to claim 1, wherein
the narrow-band filter includes a plasmonic filter using guided mode resonant (GMR).

13. The image pickup element according to claim 1, wherein
the narrow-band filter includes a plasmonic filter having a bull's-eye structure.

14. An electronic device, comprising:
an image pickup element including
a semiconductor layer in which
a first region where a first pixel in which a read pixel signal is used to generate an image is arranged and
a second region where a second pixel in which a read pixel signal is not used to generate an image is arranged
are arranged,
a narrow-band filter that is laminated on the first region on a light incident surface side of the semiconductor layer and transmits light of a desired wavelength, and
a metal film that is laminated on the second region on the light incident surface side of the semiconductor layer and has a plurality of through holes; and
a processing unit that processes a signal from the image pickup element.
